(19) United States
(12) Patent Application Publication
(10) Pub. No.: US 2025/0105085 A1
(43) Pub. Date: Mar. 27, 2025

(54) A METHOD FOR APPLYING A COOLING SOLUTION TO ONE OR MORE INTEGRATED CIRCUIT COMPONENTS AND ASSEMBLE FOR INTEGRATED CIRCUIT COOLING

(71) Applicant: Tesla, Inc., Austin, TX (US)

(72) Inventors: Mohamed Haitham Helmy Nasr, Sunnyvale, CA (US); Srikumar Seshasayee Iyengar, San Jose, CA (US); Aydin Nabovati, Toronto (CA); Surinderpal Singh Jassal, Dublin, CA (US); Aleksandar Plavsic, Mequon, WI (US)

(21) Appl. No.: 18/728,985

(22) PCT Filed: Jan. 12, 2023
(86) PCT No.: PCT/US2023/010702

§ 371 Date: Jul. 15, 2024

Related U.S. Application Data
(60) Provisional application No. 63/301,003, filed on Jan. 19, 2022.

(51) Int. Cl. H01L 23/367; H01L 23/00; H01L 23/373

(52) U.S. Cl. CPC H01L 23/367; H01L 23/3736; H01L 24/16; H01L 24/29; H01L 24/32; H01L 24/33; H01L 24/73; H01L 2224/16225; H01L 2224/29144; H01L 2224/32225; H01L 2224/32245; H01L 2224/33181; H01L 2224/73204

(57) ABSTRACT

A method can include attaching an integrated circuit to a printed circuit board in a first solder reflow process at a first reflow temperature. A method can include soldering a heat spreader to the integrated circuit in a second solder reflow process at a second reflow temperature, wherein the second reflow temperature is lower than the first reflow temperature. A method can include attaching a cold plate to the heat spreader such that a thermal interface material is positioned between the heat spreader and the cold plate. Related integrated circuit assemblies are disclosed with thermal interface material, such as solder or a liquid metal, positioned between a heat spreader and an integrated circuit. The thermal interface material has a lower melting temperature than solder on another surface of the integrated circuit.

### CROSS-REFERENCE TO RELATED APPLICATION

This application is a non-provisional of and claims priority to U.S. Provisional Patent Application No. 63/301,003, entitled “LOW TEMPERATURE SOLDERED HEAT SPREADER,” filed on Jan. 19, 2022, which is hereby incorporated by reference in its entirety and for all purposes.

### BACKGROUND

### Technical Field

This disclosure relates generally to cooling integrated circuits and methods of manufacturing integrated circuit assemblies.

### Description of Related Technology

Integrated circuits (ICs) can encounter technical challenges dissipating heat. ICs can use various cooling solutions to dissipate heat and achieving and/or sustaining computing performance. Using solder to attach an IC to a cooling solution in an IC assembly can provide desirable thermal conductivity. At the same time, solder can present technical challenges in manufacturing IC assemblies.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

In some aspects, the techniques described herein relate to a method for applying a cooling solution to one or more integrated circuit components, the method including: attaching an integrated circuit to a printed circuit board in a first solder reflow process at a first reflow temperature; soldering a heat spreader to the integrated circuit in a second solder reflow process at a second reflow temperature, wherein the second reflow spreader such that a thermal interface material is positioned between the heat spreader and the cold plate.

In some aspects, the techniques described herein relate to a method, further including, after the first solder reflow process and before the second reflow process, applying an underfill material between the printed circuit board and the integrated circuit.

In some aspects, the techniques described herein relate to a method, wherein the second reflow temperature is below a glass transition temperature of the underfill material.

In some aspects, the techniques described herein relate to a method, further including, before the second solder reflow process depositing a gold film onto at least one of a top surface of the integrated circuit or a bottom surface of the heat spreader.

In some aspects, the techniques described herein relate to a method, wherein the gold film is patterned.

In some aspects, the techniques described herein relate to a method, wherein the integrated circuit includes an internal heat spreader.

In some aspects, the techniques described herein relate to a method, wherein the integrated circuit is lidless.

In some aspects, the techniques described herein relate to a method, wherein the heat spreader has a larger footprint than the integrated circuit.

In some aspects, the techniques described herein relate to a method, wherein the cold plate is electrically connected to ground.

In some aspects, the techniques described herein relate to a method, wherein the heat spreader is electrically connected to the cold plate.

In some aspects, the techniques described herein relate to a method, wherein the printed circuit board includes a ground pad, and wherein the heat spreader is electrically connected to the ground pad.

In some aspects, the techniques described herein relate to an integrated circuit assembly with cooling for an integrated circuit, the integrated circuit assembly including: a printed circuit board; an integrated circuit including a first surface and a second surface opposite the first surface, the second surface soldered to the printed circuit board with a solder; a heat spreader positioned such that a thermal interface material is located between material is electrically conductive, wherein the thermal interface material is solid at room temperature, and wherein the thermal interface material has a lower melting temperature than the solder; and a cold plate attached to the heat spreader and in thermal communication with the heat spreader via a second thermal interface material.

In some aspects, the techniques described herein relate to an integrated circuit assembly, wherein the thermal interface material includes a second solder.

In some aspects, the techniques described herein relate to an integrated circuit assembly, wherein the thermal interface material includes a liquid metal.

In some aspects, the techniques described herein relate to an integrated circuit assembly, further including an underfill material positioned between the printed circuit board and the integrated circuit.

In some aspects, the techniques described herein relate to an integrated circuit assembly, wherein a glass transition temperature of the underfill material is greater than a melting point of the solder.

In some aspects, the techniques described herein relate to an integrated circuit assembly, further including a gold film positioned between the first surface of the integrated circuit and the heat spreader.

In some aspects, the techniques described herein relate to an integrated circuit assembly, further including an adhesion layer positioned between the first surface of the integrated circuit and the gold film.

In some aspects, the techniques described herein relate to an integrated circuit assembly, wherein the integrated circuit includes an internal heat spreader.

In some aspects, the techniques described herein relate to an integrated circuit assembly, wherein the integrated circuit is lidless.

In some aspects, the techniques described herein relate to an integrated circuit assembly, further including a deformable conductor, wherein the cold plate is electrically grounded, wherein the deformable conductor is positioned between and in contact with the heat spreader and the cold plate, and wherein the heat spreader and the cold plate are electrically connected to each other via the deformable conductor. circuit assembly, further including a deformable conductor, wherein the printed circuit board includes a ground pad, wherein the deformable conductor is disposed between and in contact with the ground pad and the heat spreader, and wherein the heat spreader and the ground pad are electrically connected to each other via the deformable conductor.

In some aspects, the techniques described herein relate to an integrated circuit assembly with cooling for an integrated circuit, the integrated circuit assembly including: a printed circuit board; an integrated circuit attached to the printed circuit board; a heat spreader soldered to the integrated circuit using a solder, wherein the solder has a reflow temperature that is below a glass transition temperature of an underfill material positioned between the printed circuit board and the integrated circuit; and a cold plate positioned over the heat spreader and thermally coupled to the integrated circuit by way of a thermal interface material.

In some aspects, the techniques described herein relate to an integrated circuit assembly, further including one or more features of the integrated circuit assemblies disclosed herein.

In some aspects, the techniques described herein relate to an integrated circuit assembly with cooling for an integrated circuit, the integrated circuit assembly including: a printed circuit board; an integrated circuit attached to the printed circuit board; a heat spreader soldered to the integrated circuit using a solder, wherein the solder has a reflow temperature that is below a reflow temperature of second solder positioned between the printed circuit board and the integrated circuit; and a cold plate positioned over the heat spreader and thermally coupled to the integrated circuit by way of a thermal interface material.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

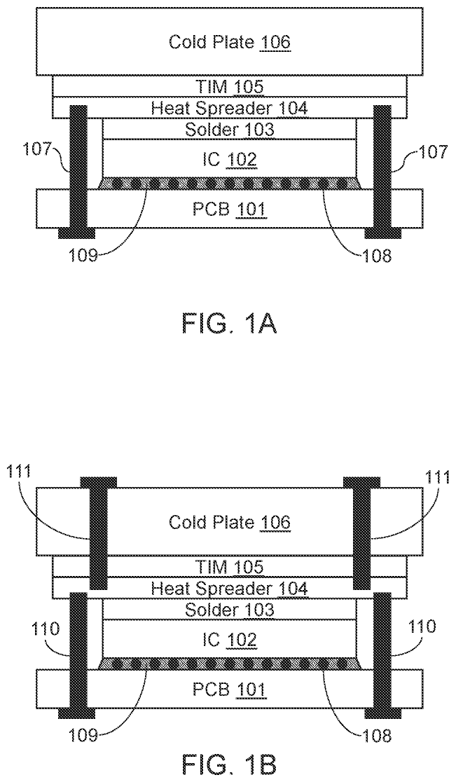

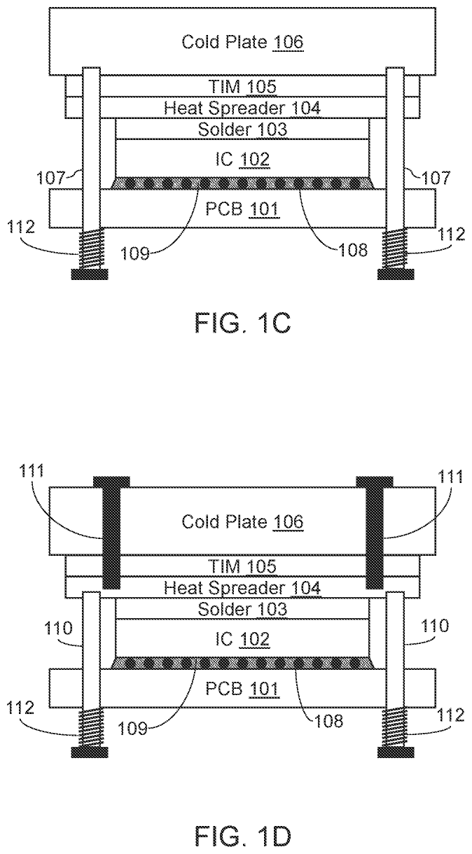

FIGS. 1A-ID are schematic cross-sectional illustrations of integrated circuit cooling configurations according to some embodiments.

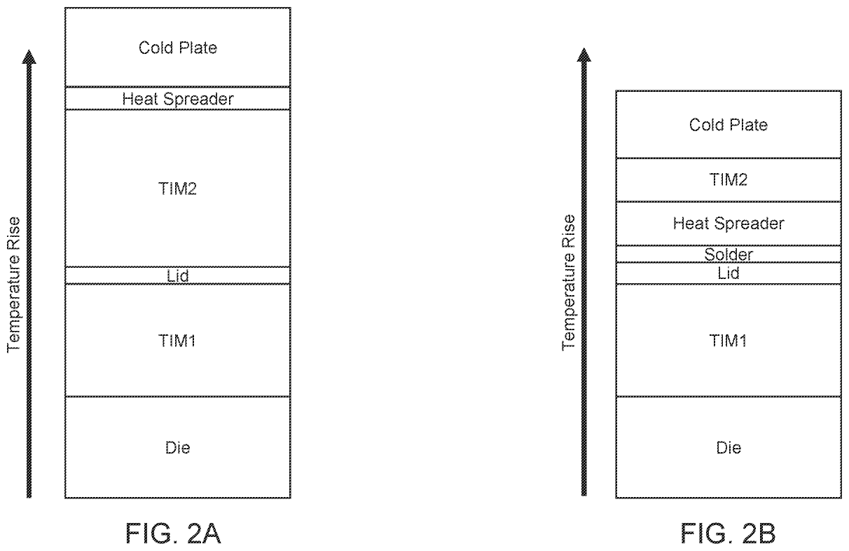

FIGS. 2A-2B are diagrams that illustrate example thermal characteristics of certain cooling structures.

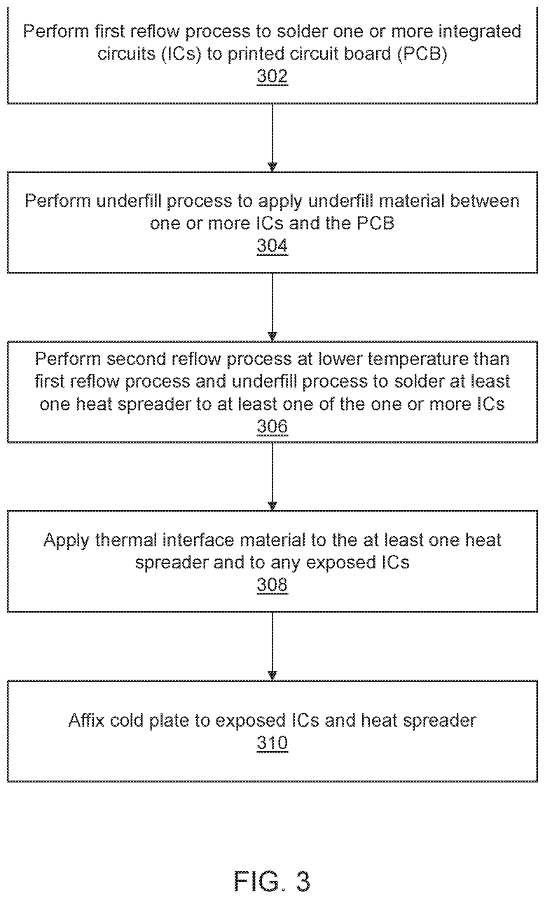

FIG. 3 is a flowchart that illustrates an example process of manufacturing an integrated circuit assembly according to some embodiments.

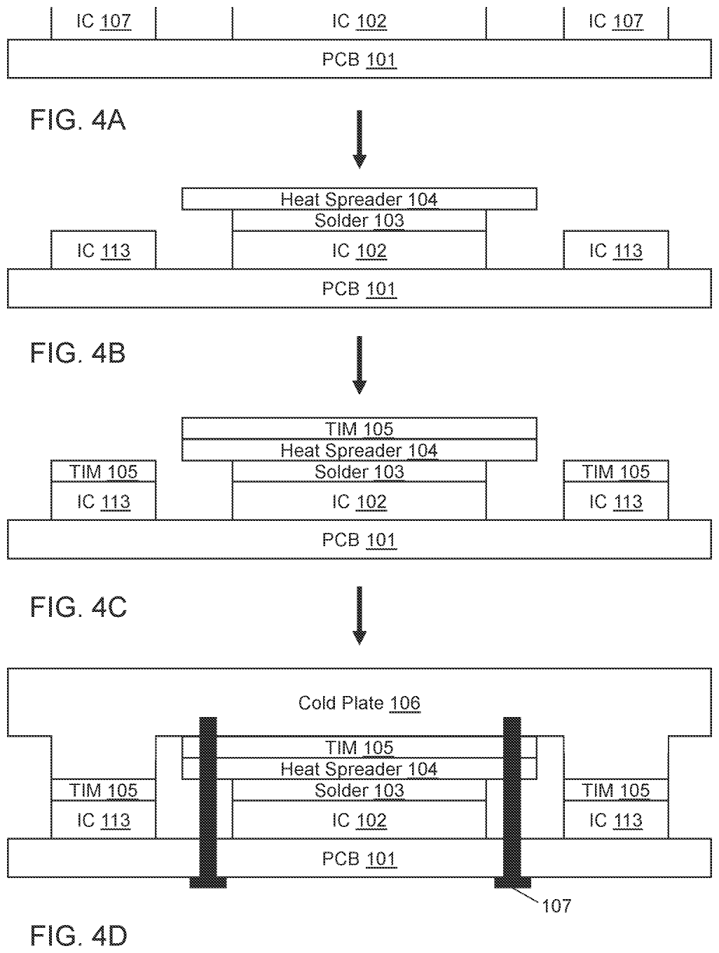

FIGS. 4A-4D illustrate schematic cross-sectional views of an integrated circuit assembly corresponding to a process for applying a cooling system to a plurality of integrated circuits according to an embodiment.

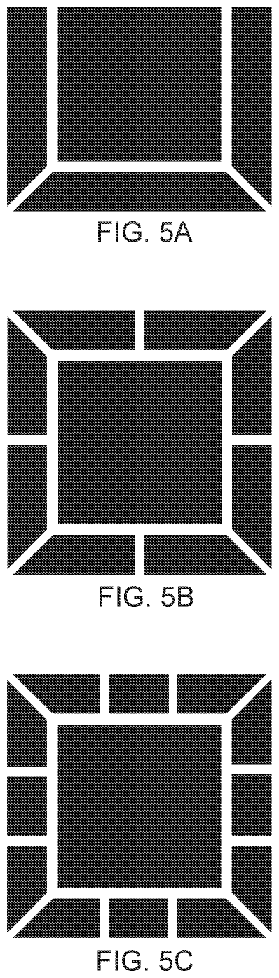

FIGS. 5A-5C are schematic illustrations of metal coating patterns according to some embodiments.

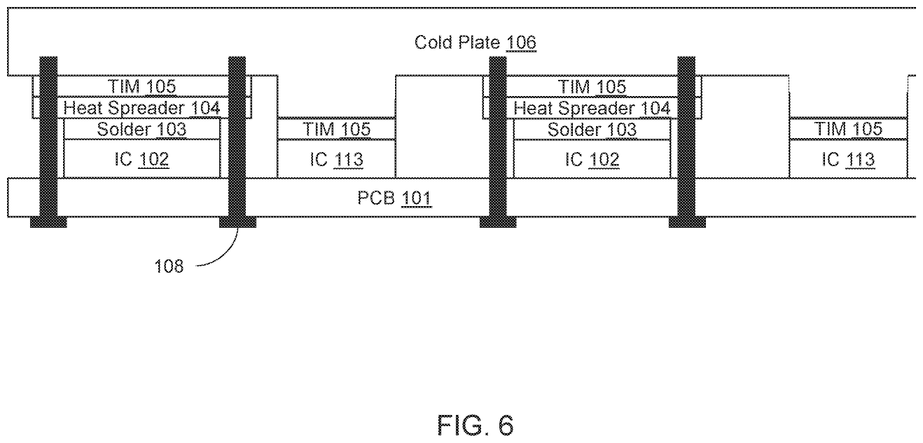

FIG. 6 is a schematic cross-sectional illustration of multi-component cooling system according to some embodiments.

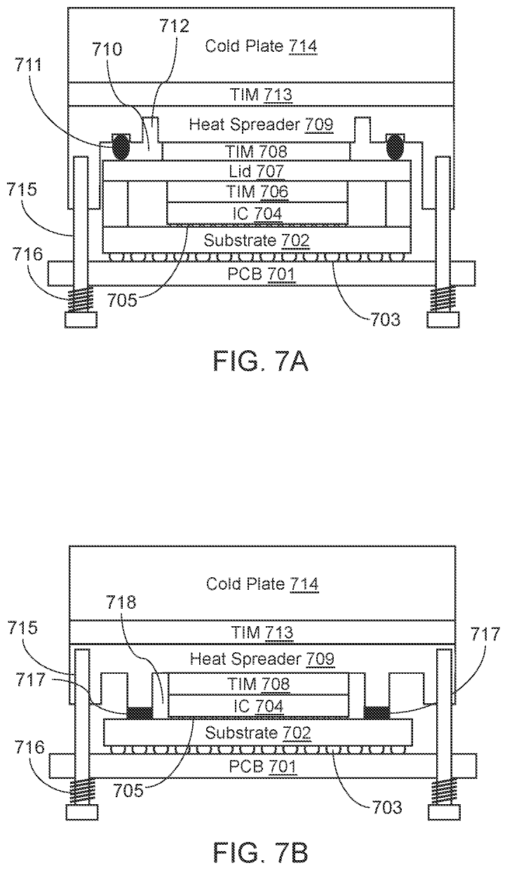

FIGS. 7A-7B are schematic cross-sectional illustrations of integrated circuit cooling configurations using liquid metal thermal interface materials according to some embodiments.

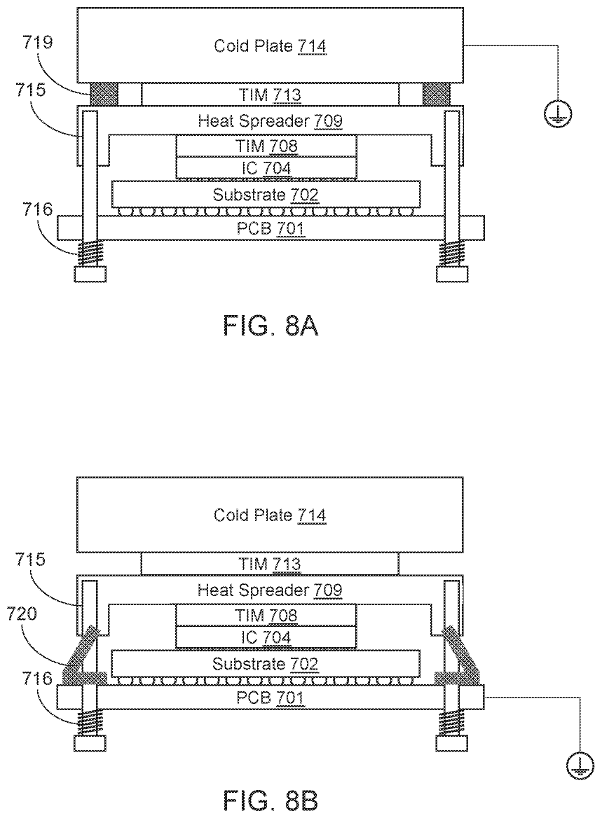

FIGS. 8A-8B are schematic cross-sectional illustrations of integrated circuit cooling configurations having a grounded heat spreader according to some embodiments.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that understood that certain embodiments can include more elements than illustrated in a drawing and/or a subset of the elements illustrated in a drawing. Further, some embodiments can incorporate any suitable combination of features from two or more drawings.

Heat can present significant technical problems for integrated circuits (ICs). For example, excess heat can lead to component damage, reduced lifetime, lower reliability, or decreased performance. In some ICs, high temperatures can cause ICs to throttle performance automatically. For example, a system on a chip (SOC), a graphics processing unit (GPU), a central processing unit (CPU), or the like may reduce the operating frequency in response to the temperature rising above a certain level. In some cases, ICs may not be able to provide adequate performance due to thermal constraints. Thus, ICs can use a variety of active cooling and/or passive cooling (e.g., fans, active liquid cooling, heat spreaders, cold plates, and so forth) solutions to dissipate heat away from IC components and maintain performance. In some embodiments, an IC uses at least a cold plate for cooling. A cold plate can include fins. A fluid can flow through the cold plate for convective heat transfer.

ICs can have lids that operate as built-in heat spreaders. These lids can face considerable constraints that may limit their effectiveness. For example, a built-in heat spreader can be constrained by the overall size of the IC package so that the heat spreader does not get in the way of other components and/or interfere with attaching the IC to a printed circuit board (PCB). Including active cooling or even more effective passive cooling could add complexity and cost that may not be desired in various applications. For example, a built-in heat spreader without additional cooling may be sufficient for a device that performs only light tasks or that operates in an environment with sufficient airflow. However, such a cooling solution may not be sufficient under heavy loads and/or in environments where ambient conditions are not favorable for passive cooling with built-in heat spreaders (e.g., due to poor airflow, high temperatures, and so forth). Thus, there is a need for additional cooling solutions when built-in heat spreaders are insufficient. In some embodiments, improved cooling solutions may lead to significantly higher performance, performance that can be sustained for longer periods, or both.

One additional cooling solution is a cold plate. Cold plates are typically attached to ICs using a thermal interface material (TIM). However, thermal interface materials attached, for example, on top of a built-in heat spreader. The interface between the cold plate and the built-in heat spreader can limit cooling efficiency because of relatively low thermal conductivity and high interface resistance of the TIM material located between the cold plate and the IC. This can be at least partially alleviated by using thermal pastes, pads, or the like. Common thermal pastes utilize a liquid carrier with a thermally conductive filler. Fillers can include, for example, aluminum oxide, aluminum nitride, zinc oxide, and silver. Typically, thermal pastes have thermal conductivities in the range of a few W/m·K, for example from about 1 W/m·K to about 10 W/m·K.

Solders offer significantly higher thermal conductivity and lower interface impedance than typical TIMs. For example, a solder may have a thermal conductivity of about 10 W/m·K, 20 W/m·K, 50 W/m·K, or 80 W/m·K or more, depending upon the specific composition of the solder. However, using solder instead of typical TIMs like thermal pastes or pads presents several technical challenges, for example, as discussed below.

In the following description, embodiments are described with reference to a single reflow process for attaching components to a PCB and a second reflow process for attaching a heat spreader to an IC. This is done for illustrative purposes only. The skilled artisan will appreciate that multiple reflow processes may be used, and the disclosure herein is not limited to only two reflow processes. For example, two, three, four, or even more reflow processes may be employed prior to a reflow process for attaching a heat spreader, and more than one reflow process may be employed for attaching heat spreaders. In certain applications, there can be two high temperature reflows performed before the low temperature solder reflow, where the two high temperature reflows include separate reflow processes to attach ICs to a top face of the PCB and to attach ICs to a bottom face of the PCB. Accordingly, the first reflow process and the second reflow process discussed herein are not necessarily the first and second reflow processes in a complete IC assembly method.

IC components may be attached to a PCB using a high temperature reflow process. For example, the reflow process may subject the PCB and components to temperatures in excess of 200 degrees Celsius or more. In certain embodiments, an underfill process may also be employed. Underfills may be used to add structure and reduce stresses that could cause cracking of ICs and/or breaking of solder joints as ICs are subjected to one or more of thermal mechanical reliability and reduce stresses driven by thermal expansion coefficient mismatches, underfill materials can present challenges for soldered cooling solutions. In some applications, underfill materials may have a glass transition temperature that is lower than the solder reflow temperature for a soldered cooling solution. For example, an underfill material may have a glass transition temperature of 125 degrees Celsius, 155 degrees Celsius, etc. Near the glass transition temperature or, depending on the material and application, above or below the glass transition temperature, the underfill may cause significant stresses in ICs or lose its ability to stiffen a ball grid array as the underfill material's structure changes and the material softens. The underfill glass transition temperature can constrain processing temperatures for later processing steps, such as additional solder reflow steps.

Accordingly, using solder as part of a cooling system presents several challenges. Attaching cooling components using solder after the ICs are attached to the PCB can cause problems related to the PCB reflow, the underfill, or both. Soldering a heat sink during PCB reflow (e.g., when the IC components are attached to the PCB) could damage (e.g., crush) the ball grid arrays used by many ICs, such as processors and SOCs. The thermal mass of the combined PCB and cold plate can, in some circumstances, involve long reflow times due to heating up relatively large amounts of material, which could result in reduced reliability of or damage to the ICs, the PCB, or other components. Attaching cooling components prior to PCB reflow could present significant challenges later in the assembly process. For example, even a lightweight cooling component could make it more difficult to place components on the PCB for a variety of reasons, such as added weight, increased physical dimensions, and so forth.

If solder is used for the cooling system (e.g., to attach components and/or to act as a thermal interface), there are advantages to applying the solder after the PCB reflow step is complete. There can also be advantages to adding a relatively small or minimum thermal mass with the solder. A low temperature solder may be used in a secondary reflow step after the PCB reflow, where the low temperature solder has a melting temperature below the melting point of the solder used for the PCB reflow. Where an underfill is used, the low temperature solder can advantageously have a melting temperature below the glass transition that can be especially pronounced when the underfill material undergoes a glass transition.

In embodiments disclosed herein, a heat spreader is soldered to an integrated circuit (IC). This can reduce the thermal mass compared with soldering a cold plate and thereby reduce the time that the PCB and ICs are exposed to elevated temperatures during an additional reflow, which can reduce the likelihood of damage to the PCB, ICs, and so forth. Additionally, in certain applications, adding less mass to the top of the IC can reduce the likelihood of damaging an electrical interface (e.g., ball grid array) of the IC. Attaching a heat spreader to an IC in a second reflow process may improve thermal performance. Additional cooling can also be implemented. Even in such cases, benefits may be realized from soldering heat spreaders to ICs before thermally coupling the combined IC and heat spreader to additional cooling hardware. The TIM can be a thermal bottleneck. Thus, in some embodiments, performance can be improved by moving the thermal bottleneck farther away from the heat source (e.g., the silicon die of an IC) relative to other designs, thereby reducing the impact of the bottleneck.

Some TIMs, especially those that achieve high thermal performance, involve applying high pressure during manufacture to achieve the most efficient thermal transfer. However, when TIMs are applied directly to integrated circuit chips, there is a risk that applying high pressure may damage the IC. For example, if a cold plate is tightened directly to an IC (or the built-in heat spreader of an IC) using screws, tight screws may achieve high and/or optimal thermal transfer. However, overtightening or uneven tightening of the screws can crack the IC and/or induce stresses in the IC that can lead to early failure. By soldering a heat spreader to the IC, a high-performance TIM may be applied between the heat spreader and a cold plate. In some applications, this interface may be subjected to high pressure without risk of damaging the IC component. Higher-performance TIMs can be used that involve higher compression without compromising electronics of the IC due to the compression occurring between a heat spreader and a cold plate.

Improved thermal performance may, in some embodiments, be achieved by attaching a heat spreader to an IC using solder in a second reflow process. In some embodiments, higher performance can be achieved. For example, improved cooling may allow provide more compute capability.

FIGS. 1A and 1B are illustrations of an integrated circuit assembly with cooling according to some embodiments. In FIGS. 1A and 1B, a PCB 101 has an IC 102 mounted thereon. In some embodiments, the IC 102 may be mounted to the PCB 101 using a ball grid array 108. The ball grid array 108 can include a plurality of solder balls. An underfill 109 can be disposed between the PCB 101 and the IC 102. The IC 102 can be an application specific integrated circuit (ASIC). The IC 102 can be a relatively high-power IC. The IC 102 can include a semiconductor die, such as a silicon die. On top of the IC 102 is a heat spreader 104 attached to the IC 102 using a low temperature solder 103. The heat spreader 104 is in thermal connection with a cold plate 106 via a TIM 105. The TIM 105 can be any suitable material for a thermal interface, such as a thermal paste or pad.

As illustrated in FIG. 1A, in some embodiments, the cold plate 106 can be secured to the PCB by one or more anchor bolts 107. FIG. 1A illustrates an embodiment in which the anchor bolts 107 extend into the heat spreader 104 but do not emerge from the heat spreader 104. In some implementations, the anchor bolts 107 can extend into the cold plate 106 but may not emerge from the cold plate 106. In some other implementations, the anchor bolts 107 can extend all the way through the cold plate 106. In such an implementation, nuts can be secured to the anchor bolts 107 at the top, exposed surface of the cold plate 106. In some implementations, it may be desirable not to extend the anchor bolts 107 beyond the heat spreader 104 in order to reduce or limit weight on the ball grid array 108 during reflow. In some embodiments, the cold plate 106 and heat spreader 104 can be affixed to one another after reflowing the low temperature solder 103. This can reduce the likelihood of crushing the ball grid array 108 while the cold plate 106 and heat spreader 104 are affixed to each other. Any other suitable fastener can be implemented in place of or in addition to an anchor bolt 107.

FIG. 1B depicts an alternative, “floating” implementation. In FIG. 1B, the IC 102, solder 103, and heater spreader 104 are electrically and mechanically connected to the PCB 101 by ball grid array 108, and underfill 109 can provide additional mechanical and/or thermal integrity. The anchor bolts 110 in FIG. 1B, in contrast to the anchor bolts 107 in FIG. 1A, may not extend into the cold plate 106. Instead, the anchor bolts 110 can extend into the the cold plate 106 to the heat spreader 104. An embodiment such as that shown in FIG. 1B can enable the cold plate 106 to be tightened against the heat spreader 104, compressing the TIM 105, with reduced risk of damage to the IC 102 and/or the PCB 101 as compared with the example shown in FIG. 1A. Any other suitable fastener can be implemented in place of or in addition to a bolt 110 and/or 111.

FIGS. 1C and 1D illustrate embodiments that are generally similar to FIGS. 1A and 1B, respectively, except that springs are included. In FIG. 1C, springs 112 are placed around the anchor bolts 107 such that the springs 112 are compressed between the heads of the anchor bolts 107 and the PCB 101 as the anchor bolts 107 are tightened. Similarly, in FIG. 1D, springs 112 are placed around the anchor bolts 110 such that the springs 112 are compressed as the anchor bolts 110 are tightened. The springs 112 can absorb forces and control the pressure on the IC 102 and other components. Absent the springs 112, it can be difficult to control the force on the IC 102 as anchor bolts 107 or 110 are tightened, which can result in damage to the IC 102, especially if the anchor bolts 107 or 110 are not tightened uniformly.

In some embodiments solder 103 can instead be another thermal interface material (e.g., thermal pad, thermal paste, curable thermal interface material, and so forth). An embodiment such as that shown in FIG. 1B and/or FIG. ID can offer significant improvement over conventional designs known to those of skill in the art. For example, while the interface between the IC 102 and the heat spreader 104 can be a conventional thermal interface material, the embodiments shown in FIG. 1B and/or FIG. 1D can be used to reduce the thermal resistance of the thermal interface layer because the thermal interface material can be compressed to a lesser thickness than would ordinarily occur using more conventional fixed gap designs and/or the presence of voids, air pockets, and so forth can be reduced.

While the drawings herein depict the use of screws or bolts to affix the cold plate to the PCB and/or to the heat spreader, as well as to attach the heat spreader and IC to the PCB (optionally using springs), it will be appreciated that other approaches are possible. For example, instead of screws or bolts, clips or other appropriate hardware can be used for affixing components to one another.

While FIGS. 1A to 1D depict example embodiments in which an integrated circuit is soldered to a PCB using a ball grid array, other surface mount techniques can the PCB using a socket and pins.

The integrated circuit assemblies of FIGS. 1A to 1D can be advantageous for several reasons. For example, the heat spreader 104 can be significantly larger than a built-in heat spreader of the IC 102. The heat spreader 104 has a larger footprint than the IC 102. The heat spreader 104 may be twice as large or four times as large as the surface area of the built-in heat spreader of the IC 102, for example. Thus, the heat produced by the IC 102 may be transferred to the heat spreader 104 and spread across a relatively large surface area before encountering the relatively lower thermal conductivity of the TIM 105. Because the heat has already been carried away from the IC 102 and spread over a larger area, the thermal performance of the TIM 105 has less of an impact on the performance of the IC 102 than certain other designs with TIM between an IC and a heat spreader. For example, the heat flux of heat spreader 104 may be ¾, ½, or less than that of the heat flux at the IC 102. For example, the heat flux may be reduced from about 25 W/cm² to about 10 W/cm².

FIGS. 2A and 2B illustrate thermal characteristics of cooling structures. FIG. 2A shows thermal characteristics that may be exhibited by a cooling structure that is not formed with low temperature soldered heat spreaders disclosed herein. In these figures, the height of components of the stack is proportional to temperature increase in each component. The combined height of each stack is proportional to combined temperature increase of the respective stack. In FIG. 2A, a die is in thermal contact with a lid via a first TIM, and the lid is in thermal contact with a heat spreader via a second TIM. A cold plate, which can include convection liquid and/or cooling fins, then rests atop the heat spreader in thermal contact with the heat spreader. FIG. 2B depicts thermal characteristics that may be exhibited by a cooling structure formed according to the disclosures herein. In FIG. 2B, a die is in contact with a lid via a first TIM, and the lid is soldered to the heat spreader. The heat spreader is then in thermal contact with a cold plate, which can include convection liquid and/or cooling fins, via a second TIM. As shown in FIG. 2A, the second TIM may be the largest contributor to temperature rise when the TIM is placed between the lid and heat spreader. In FIG. 2B, the contribution of the second TIM to the temperature rise is significantly reduced when the heat spreader is soldered to the lid and the second TIM is placed between the heat spreader and the cold plate (which temperature rise.

FIG. 3 is a flowchart that illustrates an example process 300 for forming a soldered cooling assembly according to some embodiments. At block 302, a first reflow process can be performed to solder one or more integrated circuit chips to a printed circuit board. At block 304, an underfill process can be performed to encapsulate a bottom side of one or more IC chips. It will be appreciated that in some embodiments, an underfill process may not be performed. At block 306, a second reflow process can be performed to solder at least one heat spreader to at least one IC of the one or more ICs. In some embodiments, all ICs of an IC assembly may have a heat spreader soldered thereto. In other embodiments, however, only some ICs may have heat spreaders soldered thereto, while the top surfaces of other ICs can remain exposed. For example, heat spreaders may be soldered to relatively high-power components but not to relatively low-power components. At block 308, a thermal interface material such as a pad or paste can be applied to the at least one heat spreader and to any exposed ICs. At block 310, a cold plate can be affixed over the one or more exposed ICs and/or heat spreaders and can be in contact with the ICs and/or heat spreaders via the thermal interface material.

FIGS. 4A-4D illustrate cross sectional views of an integrated circuit assembly corresponding to a process for applying a cooling system to a plurality of integrated circuits according to an embodiment. In FIG. 4A, ICs 102 and 113 are attached to a PCB 101. The ICs 102 and 113 can be attached to the PCB 101 using a high temperature reflow process. Although not illustrated in FIGS. 4A-4D, high temperature solder from the high temperature reflow process can attach the ICs 102 and 113 to the PCB 101. The IC 102 can be a relatively high-power integrated circuit. The IC 102 may be, for example, a high power application specific integrated circuit, system on a chip, power IC, or the like. The IC 102 can be a packaged integrated circuit, which can include an internal heat spreader (e.g., a lid). In some embodiments, the IC 102 can be lidless. ICs 113 may include, for example, dynamic random access memory (DRAM) and/or other components that produce less heat relative to the IC 102.

In FIG. 4B, a heat spreader 104 is affixed to the IC 102 using low temperature solder 103. As illustrated in FIG. 2B, a heat spreader may not be soldered to the lower power ICs 113. The heat spreader 104 is attached to the IC 102 using a lower temperature lower temperature reflow process can be performed at a temperature lower than a glass transition temperature of an underfill material. The lower temperature reflow process can be performed at a temperature of less than 160 degrees Celsius in certain applications. The heat spreader can be accurately positioned (e.g., to within a tolerance) and/or compressed to ensure proper contact. In some applications, the heat spreader 104 can be fixtured to the IC 102 to keep the heat spreader 104 in place during the lower temperature reflow process. For example, in some applications, force can be applied (e.g., downward force directed toward the IC 102) to keep the heat spreader 104 in place. In some applications, force may not be applied. For example, the heat spreader 104 may be sufficiently heavy that an external force is of no or limited benefit.

In FIG. 4C, a TIM 105 is applied on top of the ICs 113 and on top of the heat spreader 104. In FIG. 4D, a cold plate 106 is affixed and placed in contact with the TIM 105 on top of the ICs 113 and the heat spreader 104. The cold plate 106 may be attached to the PCB 101 using one or more anchor bolts 107. As illustrated, anchor bolts 107 pass through the heat spreader 104. Anchor bolts do not pass through a heat spreader in some other applications.

FIGS. 5A-SC are illustrations of metal coating patterns according to some embodiments. In some embodiments, a coating may be applied to the surface of the IC (e.g., to a built-in heat spreader) and/or to the heat spreader, such as the heat spreader 104 of FIGS. 1A-1D and/or FIGS. 4B-4D or the heat spreader 709 of FIGS. 7A-7B and 8A-8B. In some embodiments, the heat spreader may comprise copper, plated aluminum, anodized aluminum, another suitable material, or any suitable combination thereof. For example, the heat spreader can include copper. In some embodiments, the heat spreader may comprise nickel-plated copper. It can be significant that the joint between the IC and the heat spreader be robust. Thus, in some embodiments, a metallization layer such as, for example, a gold coating, may be used to improve the reliability of the joint. For example, a top surface of the IC 102, a bottom surface of the heat spreader 104, or both, may be coated with a metallization layer such as a gold film, which may be about 50 nm thick or greater, such as in a range from about 50 nm thick to about 100 nm thick. The metallization layer may be deposited using immersion, thermal evaporation, electron beam evaporation, or other suitable deposition processes.

IC that has a built-in heat spreader. In some other embodiments, the IC may comprise a lidless package with an exposed die. The skilled artisan will appreciate that the embodiments described herein can be applied to lidded and lidless ICs. A metallization layer, such as a gold film, may be applied to the surface of an exposed die to enable soldering of an external heat spreader such as the heat spreader 104. The heat spreader 104 may then be soldered to an IC 102 that does not have a built-in heat spreader (e.g., a lid). In certain embodiments, the metallization layer may comprise a single layer such as, for example, a single gold layer. In some other embodiments, the metallization layer may comprise multiple layers. For example, the metallization layer may comprise a chromium adhesion layer (or other suitable adhesion layer material such as tungsten, niobium, or titanium) and a gold layer.

In some embodiments, voids in the joint between the IC 102 and the heat spreader 104 may significantly impact thermal performance, the reliability of the joint, or both. In some embodiments, a vacuum reflow process may be used to reduce the presence of voids. In some embodiments, patterning the gold film can reduce the formation of voids. For example, patterning the gold film can provide channels for air and/or other gases to escape during the reflow process. FIGS. 5A-SC illustrate different patterns that may be used to reduce the formation of voids in the interface. In some embodiments, the center of the IC may be a major heat source, and thus the pattern may be solid in that region in order to increase or maximize heat transfer. The pattern can be symmetrical about a central axis. It will be appreciated that in some embodiments, other patterns may be preferable. For example, in some embodiments, an SOC may have a region with CPU cores, another region with GPU cores, and another region with a modem or other communications functionality. In some applications, it may be preferable to place solid film regions over CPU cores, or over GPU cores, and so forth, depending on the layout of the IC and the functions being performed by the IC.

FIG. 6 is an illustration of a multi-component integrated circuit assembly with a cooling system according to some embodiments. In FIG. 6, two high power ICs 102 and two low power ICs 113 are attached to a single PCB 101. The heat spreaders 104 are soldered to the high-power ICs 102 using low temperature solder 103. The heat spreaders 104 and the low power ICs 113 are in thermal contact with a single cold plate 106 via a thermal interface material 105. In some embodiments, it may be advantageous to have multiple components in components may reduce cooling cost and weight, may allow the cold plate to be significantly larger than would be possible if each component had its own cold plate, or both. However, technical problems may be encountered when using a single large cold plate for multiple components. Due to manufacturing tolerances, different components may be at different heights from the PCB, and the height may vary from one circuit board to another and from one IC to another. Thus, thick layers (for example, about 500 μm) of thermal interface material may be used to ensure that all components are in good thermal contact with the cold plate. However, because traditional thermal interface materials tend to be relatively poor thermal conductors compared to, for example, solder, thick layers of TIM may result in decreased thermal transfer performance and thus reduce the maximum operating performance of the integrated circuits. By moving the TIM away from the high-power integrated circuits, it is possible to use relatively thick TIM layers to accommodate manufacturing differences while increasing the efficiency of heat transfer from the high power integrated circuits, which may lead to increased performance. It will be appreciated that other configurations are possible. For example, in some embodiments, there may be a different number of high-power ICs 102 and low power ICs 113. In some embodiments, there may be no low power ICs.

Although some embodiments are discussed with reference to low temperature solder positioned between a heat spreader and a cold plate, any suitable thermal interface material with a relatively high thermal conductivity and a lower melting point than higher temperature solder that attaches an IC and a PCB can alternatively or additionally be used. For example, liquid metals with a melting temperature of less than about 50 degrees Celsius and having relatively low thermal resistance during operation of an IC can be used in place of low temperature solder. Such thermal interface materials can be electrically conductive. Such thermal interface materials can comprise metal. Such thermal interface materials can be solid at room temperature. Example embodiments with liquid metal as a thermal interface material positioned between a heat spreader and a cold plate will be discussed with reference to FIGS. 7A and 7B.

FIGS. 7A and 7B are illustrations of example integrated circuit assemblies with cooling according to some embodiments. In some embodiments, a floating heat spreader can be affixed to a chip using a foam, o-ring gasket, or the like to create a sealed volume, which thermal interface material can include indium-based material, gallium-based material, or another metal material that melts at relatively low temperatures, such as some alloys of bismuth or tin. Liquid metal thermal interface materials can be desirable because they can have relatively high thermal conductivities. For example, a liquid metal thermal interface material can have a thermal conductivity of from about 20 W/m·K to about 80 W/m·K, for example from about 20 W/m·K to about 50 W/m·K, or more. Typically, such materials can have a melting temperature below about 50 degrees Celsius, and thus can be liquid during operation of an integrated circuit. Thus, it can be important to confine the liquid metal thermal interface material to ensure that it does not spread to undesirable locations.

FIG. 7A illustrates a floating design that can be implemented on a lidded integrated circuit. As shown in FIG. 7A, a substrate 702 can be affixed to a PCB 701. The substrate 702 and PCB 701 can be electrically and mechanically joined by ball grid array 703. The ball grid array 703 can include high temperature solder balls. In some embodiments, an underfill can be used between the substrate 702 and the PCB 701. An IC 704 can be mechanically and electrically attached to the substrate 702 via a second ball grid array 705. In some embodiments, an underfill can be present between the substrate 702 and IC 704. A thermal interface material 706 can be formed on top of the IC 704 and can enable thermal communication between the IC 704 and a lid 707. A second thermal interface material 708 can be formed on top of the lid 707, and a heat spreader 709 can be disposed on top of the lid 707 and second thermal interface material 708. The second thermal interface material 708 can be a liquid metal thermal interface material. The second thermal interface material 708 has a lower melting temperature than high temperature solder balls of the ball grid array 703. The lid 707 and heat spreader 709 can define a cavity 710 that is sealed using o-ring gaskets 711. While an o-ring gasket is depicted in FIG. 7A, it will be appreciated that other forms of rings or gaskets can be used to seal the cavity 710. The cavity can include one or more overflow trenches 712 in the heat spreader 709 that can hold excess liquid. Ensuring that liquid does not escape the cavity 710 can avoid short circuiting any electronics that could be exposed to the liquid. The heat spreader 709 can be in thermal communication with a cold plate 714 via thermal interface material 713. Anchor bolts 715 can pass through the PCB 701 and screw into the heat spreader 709 to provide mechanical stability. As discussed above with reference to FIGS. 1C and 1D, torquing of the anchor bolts 715.

While FIG. 7A illustrates an embodiment with a lidded IC, a similar structure can be used with a lidless IC, for example, as illustrated in FIG. 7B. Unlike FIG. 7A, the embodiment shown in FIG. 7B does not include a lid 707. Instead, the heat spreader 709 can be in thermal communication with the IC 704 via second thermal interface material 708, which can be a liquid metal thermal interface material. In FIG. 7B, the heat spreader 709 and substrate 702 can form a cavity 718. The cavity 718 can be sealed by gasket 717, which can be, for example, a rubber gasket, a foam gasket, and so forth. It will be appreciated that a lidded IC could also be used in an assembly similar to that shown in FIG. 7B. For example, if the lid of a lidded IC does not extend to the end of the substrate, the heat spreader and substrate can be used to form a sealed cavity similar to the one shown in FIG. 7B.

In some assemblies, a heat spreader can be electrically grounded. Various approaches can be used for grounding the heat spreader. For example, in some embodiments, a cold plate can be grounded, and the heat spreader can be grounded through the cold plate. In some embodiments, the heat spreader can be grounded through a PCB.

FIG. 8A is an illustration of an example embodiment in which the heat spreader 709 is in electrical communication with cold plate 714 via a conductive gasket 719. The heat spreader 709 can be electrically connected to the cold plate via any suitable electrical connection, such as a conductive foam, conductive o-ring, conductive spring, or another deformable conductor. The cold plate 714 can be connected to ground.

In some embodiments, the cold plate 714 may not be connected to ground and the heat spreader 709 can instead be grounded through the PCB 701, for example, as shown in FIG. 8B. Conductive spring fingers 720 can electrically connect the heat spreader 709 to the PCB 701. The conductive spring fingers 720 can deform as the anchor bolts 715 are tightened and the heat spreader 709 comes closer to the PCB 701. The conductive spring fingers 720 can be in contact with one or more grounding pads (not shown) on the PCB 701. Any other suitable conductive structure to electrically connect the cold plate 714 to the PCB 701 can be implemented in place of or in addition to conductive spring fingers 720.

While FIGS. 8A and 8B illustrate assemblies that are similar to those shown in FIGS. 7A and 7B, it will be appreciated that grounded heat spreaders can be implemented in FIGS. 1A-1D and FIG. 6.

Integrated circuit assemblies disclosed herein can be implemented in a variety of contexts. For example, such integrated circuit assemblies can be used for automotive electronics, such as electronics for autonomous driving and/or driver assistance features. The integrated circuit assemblies disclosed herein can be implemented in any suitable system that can benefit from the cooling provided by such systems. For instance, high performance computing and/or computation intensive applications, such as neural network processing, machine learning, artificial intelligence training, or the like, can benefit from the cooling provided by the integrated circuit assemblies disclosed herein.

### Additional Embodiments

In the foregoing specification, the disclosure has been described with reference to specific embodiments. It will, however, be evident that various modifications and changes may be made thereto without departing from the broader spirit and scope of the disclosure. The specification and drawings are, accordingly, to be regarded in an illustrative rather than restrictive sense.

Indeed, although this disclosure is in the context of certain embodiments and examples, it will be understood by those skilled in the art that the inventions extend beyond the specifically disclosed embodiments to other alternative embodiments and/or uses of the inventions and equivalents thereof. In addition, while several variations of the embodiments have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments disclosed herein. Any methods disclosed herein need not be performed in the order recited. Thus, it is intended that the scope of the disclosure should not be limited by the particular embodiments described above.

It will be appreciated that the systems and methods of the disclosure each have several innovative aspects, no single one of which is solely responsible or required for may be used independently of one another or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will also be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. In addition, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Further, while the methods and devices described herein may be susceptible to various modifications and alternative forms, specific examples thereof have been shown in the drawings and are herein described in detail. It should be understood, however, that the disclosure is not to be limited to the particular forms or methods disclosed, but, to the contrary, the disclosure is to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (e.g., as accurate as reasonably possible under the circumstances, for example ±5%, ±10%, ±15%, etc.). Phrases preceded by a term such as “substantially” include the recited phrase and should be interpreted based on the circumstances (e.g., as much as reasonably possible under the circumstances). For example, standard conditions including temperature and pressure.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the widest scope consistent with this disclosure, the principles and the novel features disclosed herein.

1. A method for applying a cooling solution to one or more integrated circuit components, the method comprising:
attaching an integrated circuit to a printed circuit board in a first solder reflow process at a first reflow temperature;
applying an underfill material between the printed circuit board and the integrated circuit;
soldering a heat spreader to the integrated circuit in a second solder reflow process at a second reflow temperature after the applying the underfill material, wherein the second reflow temperature is lower than a glass transition temperature of the underfill material; and
attaching a cold plate to the heat spreader such that a thermal interface material is positioned between the heat spreader and the cold plate.

2. (canceled)

3. The method of claim 1, wherein the second reflow temperature is less than 160 degrees Celsius.

4. The method of claim 1, further comprising, before the second solder reflow process depositing a gold film onto at least one of a top surface of the integrated circuit or a bottom surface of the heat spreader.

5. The method of claim 4, wherein the gold film is patterned.

6. (canceled)

7. (canceled)

8. The method of claim 1, wherein the heat spreader has a larger footprint than the integrated circuit.

9. The method of claim 1, wherein the cold plate is electrically connected to ground.

10. The method of claim 9, wherein the heat spreader is electrically connected to the cold plate.

11. The method of claim 1, wherein the printed circuit board comprises a ground pad, and wherein the heat spreader is electrically connected to the ground pad.

12. An integrated circuit assembly with cooling for an integrated circuit, the integrated circuit assembly comprising:
a printed circuit board;
an integrated circuit comprising a first surface and a second surface opposite the first surface, the second surface soldered to the printed circuit board with a solder;
a heat spreader positioned such that a first thermal interface material is located between the heat spreader and the first surface of the integrated circuit, wherein the first thermal interface material is electrically conductive, wherein the first thermal interface material is solid at room temperature, and wherein the first thermal interface material has a lower melting temperature than the solder; and
a cold plate attached to the heat spreader and in thermal communication with the heat spreader via a second thermal interface material, the cold plate configured to convectively transfer heat.

13. The integrated circuit assembly of claim 12, wherein the first thermal interface material comprises a second solder.

14. The integrated circuit assembly of claim 12, wherein the first thermal interface material comprises a liquid metal.

15. The integrated circuit assembly of claim 12, further comprising an underfill material positioned between the printed circuit board and the integrated circuit.

16. The integrated circuit assembly of claim 15, wherein a glass transition temperature of the underfill material is greater than a melting point of the solder.

17. The integrated circuit assembly of claim 12, further comprising a gold film positioned between the first surface of the integrated circuit and the heat spreader.

18. The integrated circuit assembly of claim 17, further comprising an adhesion layer positioned between the first surface of the integrated circuit and the gold film.

19. The integrated circuit assembly of claim 12, wherein the integrated circuit comprises an internal heat spreader.

20. The integrated circuit assembly of claim 12, wherein the integrated circuit is lidless.

21. The integrated circuit assembly of claim 12, further comprising a deformable conductor,
wherein the cold plate is electrically grounded,
wherein the deformable conductor is positioned between and in contact with the heat spreader and the cold plate, and
wherein the heat spreader and the cold plate are electrically connected to each other via the deformable conductor.

22. The integrated circuit assembly of claim 12, further comprising a deformable conductor,
wherein the printed circuit board comprises a ground pad,
wherein the deformable conductor is disposed between and in contact with the ground pad and the heat spreader, and
wherein the heat spreader and the ground pad are electrically connected to each other via the deformable conductor.

23. An integrated circuit assembly with cooling for an integrated circuit, the integrated circuit assembly comprising:
a printed circuit board;
an integrated circuit attached to the printed circuit board;
a heat spreader soldered to the integrated circuit using a solder, wherein the solder has a reflow temperature that is below a glass transition temperature of an underfill material positioned between the printed circuit board and the integrated circuit; and
a cold plate positioned over the heat spreader and thermally coupled to the integrated circuit by way of a thermal interface material.

24. (canceled)
